(19) United States
(12) Patent Application Publication
(10) Pub. No.: US 2024/0324426 A1
(43) Pub. Date: Sep. 26, 2024

(54) DISPLAY PANEL

(71) Applicant: Samsung Display Co., Ltd., Yongin-Si (KR)

(72) Inventors: Haseok Jeon, Yongin-si (KR); Jihyun Kim, Yongin-si (KR); Chanyoung Kim, Yongin-si (KR); Choongyoul Im, Yongin-si (KR); Hyunduck Cho, Yongin-si (KR); Kookhyun Choi, Yongin-si (KR); Beohmrock Choi, Yongin-si (KR)

(21) Appl. No.: 18/589,437

(22) Filed: Feb. 28, 2024

(30) Foreign Application Priority Data
Mar. 24, 2023 (KR) 10-2023-0039077
Mar. 31, 2023 (KR) 10-2023-0042857

(51) Int. Cl. H10K 59/80; H10K 59/122; H10K 59/35; H10K 59/38

(52) U.S. Cl. CPC H10K 59/8792; H10K 59/122; H10K 59/352; H10K 59/38

(57) ABSTRACT

A display panel includes a display layer and an optical functional layer on the display layer, wherein the display layer includes a pixel electrode, a pixel-defining layer including a first opening defining an emission area on the pixel electrode, and an emission layer arranged in the first opening, the optical functional layer includes a black matrix in a first layer covering the pixel electrode, the black matrix including a second opening above the first opening and a color filter in the second opening, and the black matrix includes an optical split portion extending across the pixel electrode that is under the first layer.

### CROSS-REFERENCE TO RELATED APPLICATIONS

This application is based on and claims priority under 35 U.S.C. § 119 to Korean Patent Applications Nos. 10-2023-0039077 and 10-2023-0042857, respectively filed on Mar. 24, 2023 and Mar. 31, 2023 in the Korean Intellectual Property Office, the disclosures of which are incorporated by reference herein in their entirety.

### BACKGROUND

### 1. Field

One or more embodiments relate to a display panel and a display apparatus including the same.

### 2. Description of the Related Art

Recently, display apparatuses are becoming used in more diversified applications. Display apparatuses have become thinner and lighter, allowing them to be used in manners that were previously not practical.

As display apparatuses are used for various purposes, there may be various methods of designing shapes of display apparatuses, and functions which may be connected to or associated with display apparatuses are increasing.

### SUMMARY

One or more embodiments include a display apparatus for minimizing a loss of aperture ratio, preventing external light reflection, and having improved display quality. However, these are examples of benefits and do not limit the scope of the disclosure.

Additional aspects will be set forth in part in the description which follows and, in part, will be apparent from the description, or may be learned by practice of the presented embodiments of the disclosure.

According to one or more embodiments, a display panel includes a display layer and an optical functional layer on the display layer, wherein the display layer includes a pixel electrode, a pixel-defining layer including a first opening defining an emission area on the pixel electrode, and an emission layer arranged in the first opening, the optical functional layer includes a black matrix in a first layer covering the pixel electrode, the black matrix including a second opening above the first opening and a color filter in the second opening, and the black matrix includes an optical split portion extending across the pixel electrode that is under the first layer.

The second opening may include a 2-1^{st} opening and a 2-2^{nd} opening with the optical split portion therebetween.

The color filter in the 2-1^{st} opening may include a same material as the color filter in the 2-2^{nd} opening.

The first opening may partially overlap the 2-1^{st} opening and the 2-2^{nd} opening.

The optical split portion may extend across the first opening that is under the first layer.

The pixel-defining layer may be in a second layer that is covering pixel electrode, the pixel-defining layer including a display split portion that extends across the pixel electrode that is under the second layer, and the display split portion divides the first opening into a 1-1^{st} opening and a 1-2^{nd} opening.

The display split portion may overlap the optical split portion.

A first central width of the display split portion may be the same as a second central width of the optical split portion.

The 1-1^{st} opening and the 1-2^{nd} opening may have a closed shape.

The 1-1^{st} opening and the 1-2^{nd} opening may have a circular or an oval shape.

According to one or more embodiments, a display panel includes a unit pixel area defined in a first direction and a second direction perpendicular to the first direction, wherein, in the unit pixel area, a first display element emitting light of a first color and a second display element emitting light of a second color are arranged to be adjacent to each other in the first direction, and a third display element emitting light of a third color is arranged to be adjacent to the first display element and the second display element in the second direction, the third display element includes a third pixel electrode, a pixel-defining layer including a first opening defining a third emission area on the third pixel electrode, and a black matrix in a first layer that is covering the pixel electrode, the black matrix including a second opening above the first opening, and the black matrix includes an optical split portion that extends across the third pixel electrode that is under the first layer.

The second opening may include a 2-1^{st} opening and a 2-2^{nd} opening with the optical split portion therebetween.

The display panel may further include a color filter selectively transmitting the light of the third color, wherein the color filter is in the 2-1^{st} opening and the 2-2^{nd} opening.

The first opening may partially overlap the 2-1^{st} opening and the 2-2^{nd} opening.

The optical split portion may extend across the first opening that is under the first layer.

The pixel-defining layer may include a display split portion in a second layer that is covering the third pixel electrode, the display split portion extending across the third pixel electrode, and the first opening may include a 1-1^{st} opening and a 1-2^{nd} opening with the display split portion therebetween.

The display split portion may overlap the optical split portion.

A central width of the display split portion may be the same as a central width of the optical split portion.

The 1-1^{st} opening and the 1-2^{nd} opening may have a closed shape.

The first color may be red, the second color may be green, and the third color may be blue.

These general and specific embodiments may be implemented by using a system, a method, a computer program, or a combination of the system, the method, and the computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIGS. 2 to 4 are schematic cross-sectional views illustrating a portion of a section of a display apparatus according to an embodiment;

FIG. 5 illustrates arrangement of pixels according to an embodiment;

FIGS. 6A and 6B are example views for describing light reflection by an external light source;

FIG. 7A illustrates an emission area according to an embodiment;

FIG. 7B is an example view for describing light reflection by an external light source;

FIG. 8A is a plan view illustrating arrangement of an emission area of a pixel, a pixel-defining layer, and a black matrix, according to an embodiment;

FIG. 8B is a cross-sectional view of a region taken along a line II-II′ of FIG. 8A;

FIG. 9A is a plan view illustrating arrangement of an emission area of a pixel, a pixel-defining layer, and a black matrix, according to an embodiment; and

FIG. 9B is a cross-sectional view of a region taken along a line III-III′ of FIG. 9A.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

In this specification, the expression “A and/or B” may indicate A, B, or A and B. Also, in this specification, the expression “at least one of A and B” may indicate A, B, or A and B.

In embodiments described hereinafter, “lines extending in a first direction or a second direction” denotes not only the lines extending as a linear shape, but also the lines extending in the first direction or the second direction as a zig-zag shape or a circular shape.

In the embodiments hereinafter, the expression “planar” indicates a shape when an object is viewed from above, and the expression “cross-sectional” indicates a shape when an object, which is vertically cut, is seen from a lateral perspective. In the embodiments hereinafter, when a first element “overlaps” a second element, it denotes that the first element is arranged above or below the second element.

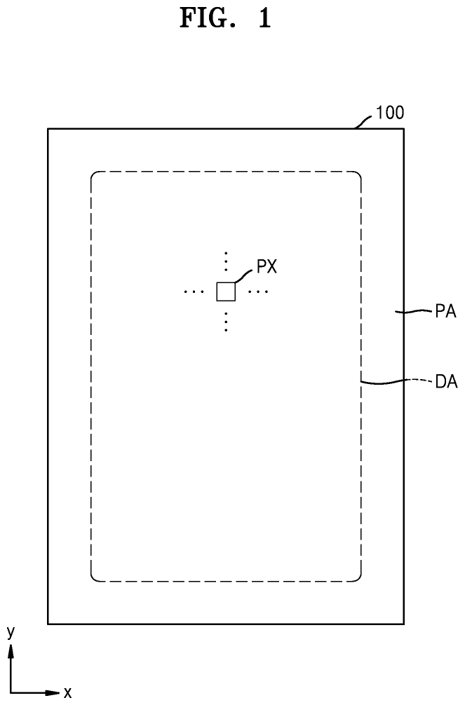

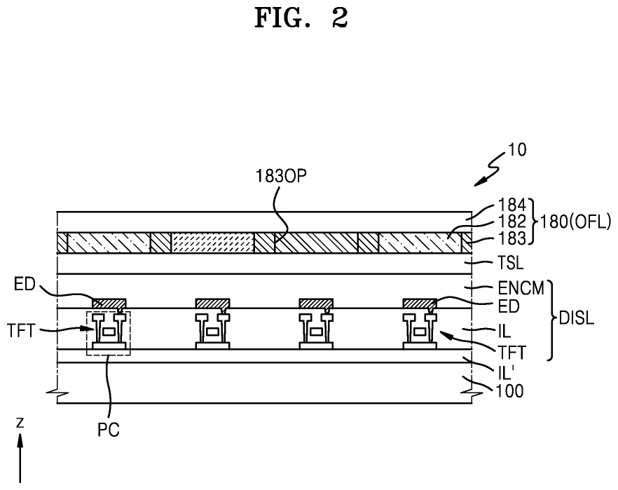

FIG. 1 is a schematic plan view of a display apparatus according to an embodiment. FIGS. 2 to 4 are schematic cross-sectional views illustrating a portion of a section of the display apparatus according to an embodiment.

Referring to FIG. 1, the display apparatus may include a display panel 10. Also, a cover window (not shown) protecting the display panel 10 may be arranged above the display panel 10.

The display panel 10 may include a display area DA realizing an image and a peripheral area PA outside the display area DA. The peripheral area PA may be a type of non-display area characterized by absence of pixels PX. The display area DA may be entirely surrounded by the peripheral area PA. Various elements included in the display panel 10 may be arranged on a substrate 100. Thus, it may be understood that the substrate 100 is in the display area DA and the peripheral area PA.

A plurality of pixels PX may be arranged in the display area DA. The pixel PX may include a display element. The display element may be connected to a pixel circuit configured to drive the pixel PX. According to an embodiment, the display element may include an organic light-emitting diode OLED. Each pixel PX may emit, for example, red, green, blue, or white light through the organic light-emitting diode OLED.

In a plan view, the display area DA may have a rectangular shape as illustrated in FIG. 1. According to another embodiment, the display area DA may have a polygonal shape, such as a triangular shape, a pentagonal shape, a hexagonal shape, etc., a circular shape, an oval shape, an amorphous shape, etc.

The peripheral area PA may be arranged around the display area DA and may not display an image. External circuits electrically connected to various lines and pixel circuits configured to transmit electrical signals that are to be applied to the display area DA, as well as pads to which a printed circuit board (PCB) or a driver integrated circuit (IC) chip is coupled may be arranged in the peripheral area PA.

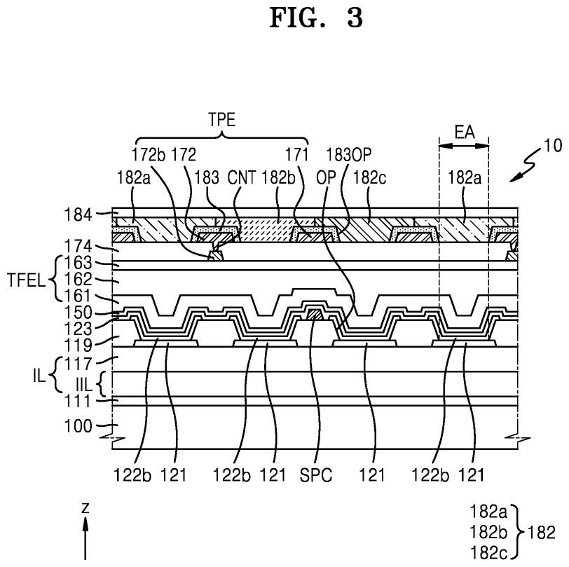

Referring to FIGS. 2 and 3, the display panel 10 may include the substrate 100, and a display layer DISL, a touch screen layer TSL, and an optical functional layer OFL on the substrate 100.

The display layer DISL may include a pixel circuit PC including a thin-film transistor TFT, an emitting diode (ED), which is a display element, and an encapsulation member ENCM, such as a thin-film encapsulation layer TFEL or a sealing substrate (not shown). Insulating layers IL and IL′ may be arranged between the substrate 100 and the display layer DISL and within the display layer DISL. In FIG. 3, the pixel circuit PC is omitted for convenience of illustration.

The substrate 100 may include a single layer including a glass material. Alternatively, the substrate 100 may include polymer resins. The substrate 100 including polymer resins may have a layered structure in which an organic layer and an inorganic layer including polymer resins are stacked. The substrate 100 may include a rigid substrate or a flexible substrate, which may be bent, folded, or rolled.

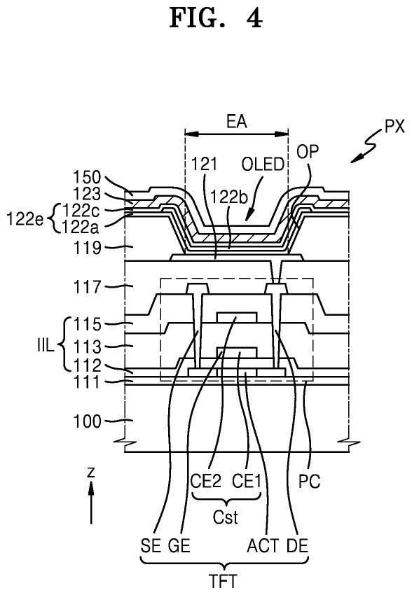

FIG. 4 depicts a buffer layer 111, an inorganic insulating layer IIL, and a planarization layer 117 that may be sequentially stacked on the substrate 100. The planarization layer 117 may include an organic material or an inorganic material and may have a single-layered structure or a layered structure. The pixel circuit PC may be arranged between the buffer layer 111 and the planarization layer 117. As illustrated in FIG. 4, the pixel circuit PC may include a thin-film transistor TFT and a capacitor Cst.

The thin-film transistor TFT may include a semiconductor layer ACT including amorphous silicon, polycrystalline silicon, or an organic semiconductor material such as an oxide semiconductor, a gate electrode GE, a source electrode SE, and a drain electrode DE. The capacitor Cst may include a lower electrode CE1 and an upper electrode CE2.

The semiconductor layer ACT may be arranged on the buffer layer 111. A first insulating layer 112 may be arranged between the semiconductor layer ACT and the gate electrode GE. A second insulating layer 113 may be arranged above the gate electrode GE, and the upper electrode CE2 of the capacitor Cst may be arranged above the second insulating layer 113. The upper electrode CE2 may overlap the gate electrode GE therebelow. The gate electrode GE and the upper electrode CE2 overlapping each other with the second insulating layer 113 therebetween may form the capacitor Cst. The gate electrode GE may be the lower electrode CE1 of the capacitor Cst. A third insulating layer 115 may be arranged above the capacitor Cst, and the source electrode SE and the drain electrode DE may be arranged on the third insulating layer 115.

Each of the first insulating layer 112, the second insulating layer 113, and the third insulating layer 115 may include an inorganic material, such as silicon oxide, silicon nitride, and/or silicon oxynitride. The first insulating layer 112, the second insulating layer 113, and the third insulating layer 115 may be commonly referred to as the inorganic insulating layer IIL.

The buffer layer 111 including an inorganic material, such as silicon oxide, silicon nitride, and/or silicon oxynitride, may be arranged between the thin film transistor TFT and the substrate 100.

The planarization layer 117 may be arranged on the thin-film transistor TFT. The planarization layer 117 may include, for example, an organic material, such as acryl, benzocyclobutene (BCB), or hexamethyldisiloxane (HMDSO). The planarization layer 117 may include an inorganic insulating material, such as SiOₓ, SiNₓ, SiON, Al₂O₃, TiO₂, Ta₂O₅, HfO₂, or ZnO₂. When forming the planarization layer 117, chemical mechanical polishing may be performed on an upper surface of a layer that is formed, in order to provide a flat upper surface. The planarization layer 117 may include a single layer or layers.

An organic light-emitting diode OLED, which is a display element, may be arranged above the planarization layer 117, as the emitting diode ED. The organic light-emitting diode OLED may include a pixel electrode 121, an opposite electrode 123, and an intermediate layer between the pixel electrode 121 and the opposite electrode 123.

The pixel electrode 121 may be arranged above the planarization layer 117, and the pixel electrode 121 may contact the source electrode SE or the drain electrode DE through a via-hole of the planarization layer 117 to be electrically connected to the thin-film transistor TFT.

A pixel-defining layer 119 may be arranged on the planarization layer 117. The pixel-defining layer 119 may cover an edge of the pixel electrode 121 and may have an opening OP exposing a portion of the pixel electrode 121. A size and a shape of an emission area EA of the organic light-emitting diode OLED may be defined by the opening OP.

The pixel-defining layer 119 may include a transparent insulating material or a non-transparent insulating material. According to an embodiment, the pixel-defining layer 119 may include an organic insulating material, such as polyimide, polyamide, acryl resins, BCB, HMDSO, phenol resins, etc. According to another embodiment, the pixel-defining layer 119 may include an inorganic insulating material, such as silicon nitride or silicon oxide, or an organic insulating material and an inorganic insulating material.

According to some embodiments, the pixel-defining layer 119 may include a light-shielding material and may be provided as a black color. The light-shielding material may include a resin or paste including carbon black, a carbon nano-tube, and a black dye, a metal particle, such as Ni, Al, Mo, and an alloy thereof, a metal oxide particle (for example, chromium oxide), a metal nitride particle (for example, chromium nitride), or the like. When the pixel-defining layer 119 includes the light-shielding material, reflection of external light due to metal structures arranged below the pixel-defining layer 119 may be reduced.

As illustrated in FIG. 3, a spacer SPC may further be arranged above the pixel-defining layer 119. According to an embodiment, the spacer SPC may include the same material as the pixel-defining layer 119. In this case, the pixel-defining layer 119 and the spacer SPC may be formed together by a mask process using a halftone mask, etc., and the spacer SPC may have an island shape protruding from the pixel-defining layer 119 by a predetermined distance in a z direction. According to another embodiment, the spacer SPC may include a different material from the pixel-defining layer 119. In this case, the spacer SPC may be insulating patterns having an island shape that are arranged above the pixel-defining layer 119 to be apart from each other by a predetermined distance.

As illustrated in FIG. 4, the intermediate layer include an emission layer 122b and an organic functional layer 122e above and/or below the emission layer 122b.

The emission layers 122b may be arranged in the opening OP of the pixel-defining layer 119 to correspond to the pixel electrode 121. The emission layer 122b may include a high-molecular weight material or a low-molecular weight material and may emit red, green, blue, or white light.

The organic functional layer 122e may include a first functional layer 122a and/or a second functional layer 122c. The first functional layer 122a or the second functional layer 122c may be omitted.

The first functional layer 122a may be arranged below the emission layer 122b. The first functional layer 122a may include a single layer or layers including an organic material. The first functional layer 122a may include a hole transport layer (HTL) having a single-layered structure. Alternatively, the first functional layer 122a may include a hole injection layer (HIL) and an HTL. The first functional layer 122a may be integrally formed to correspond to the organic light-emitting diodes OLEDs included in the display area DA.

The second functional layer 122c may be arranged above the emission layer 122b. The second functional layer 122c may include a single layer or layers including an organic material. The second functional layer 122c may include an electron transport layer (ETL) and/or an electron injection layer (EIL). The second functional layer 122c may be integrally formed to correspond to the organic light-emitting diodes OLEDs included in the display area DA.

The opposite electrode 123 may be arranged above the emission layer 122b. An upper layer 150 including an organic material may be arranged on the opposite electrode 123.

Although not shown, according to an embodiment, the intermediate layer may include at least two emitting units sequentially stacked between the pixel electrode 121 and the opposite electrode 123, and a charge generation layer (CGL) arranged between the at least two emitting units. When the intermediate layer includes the emitting units and the CGL, the organic light-emitting diode OLED may be a tandem emitting diode. When the organic light-emitting diode OLED has a stack structure of a plurality of emitting units, the organic light-emitting diode OLED may have improved color purity and emission efficiency.

One emitting unit may include an emission layer and a first functional layer and a second functional layer below and above the emission layer, respectively. The CGL may include a negative charge generation layer and a positive charge generation layer. Based on the negative charge generation layer and the positive charge generation layer, the emission efficiency of the organic light-emitting diode OLED, which is a tandem emitting diode including a plurality of emission layers, may be further increased. The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

The upper layer 150 may be provided to protect the opposite electrode 123 as well as increase the light extraction efficiency. The upper layer 150 may include LiF. Alternatively, the upper layer 150 may additionally include an inorganic insulating material, such as SiOₓ, SiNₓ, etc.

The display elements may be covered by the thin-film encapsulation layer TFEL. According to an embodiment, the thin-film encapsulation layer TFEL may include at least one inorganic encapsulation layer and at least one organic encapsulation layer. For example, the thin-film encapsulation layer TFEL may include a first inorganic encapsulation layer 161, a second inorganic encapsulation layer 163, and an organic encapsulation layer 162 therebetween.

The touch screen layer TSL may be arranged above the inorganic encapsulation layer 163. The touch screen layer TSL may obtain coordinate information based on an external input, for example, a touch event. The touch screen layer TSL may sense an external input based on a magnetic capacitance method or a mutual capacitance method. The touch screen layer TSL may include touch electrodes TPE and lines connected to the touch electrodes TPE. The touch electrodes TPE may include first touch electrodes 171 and second touch electrodes 172. The first touch electrodes 171 may be connected to each other by connection electrodes arranged on the same layer as the first touch electrodes 171. The second touch electrodes 172 may be connected to each other by connection electrodes 172b arranged on a different layer from the second touch electrodes 172 and a contact hole CNT of an insulating layer 174. The touch electrodes TPE may be arranged to correspond to the pixel-defining layer 119.

The optical functional layer OFL may include a color filter 182, a black matrix 183, and a filter layer 180 including an overcoat layer 184. The black matrix 183 may cover the first touch electrodes 171 and the second touch electrodes 172. The black matrix 183 may be arranged to correspond to the pixel-defining layer 119. The overcoat layer 184 may include an organic material, such as resins, and the organic material may be transparent.

The display panel 10 using the color filter 182 and the black matrix 183 as the optical functional layer OFL, rather than a polarization plate or a polarization film, may have improved emission efficiency of a display element. Thus, power consumption of the display panel 10 may be reduced, and brightness of the display panel 10 may be increased, to improve the lifespan of the display panel 10. Also, with a reduced emission area compared to a previous emission area, the brightness/the lifespan equal to or greater than the brightness/the lifespan of a previous display panel may be obtained. Also, by not using a polarization plate or a polarization film, a thickness of the display panel may be reduced.

The color filter 182 may include a first color filter 182a selectively transmitting only light of a first color, a second color filter 182b selectively transmitting only light of a second color, and a third color filter 182c selectively transmitting only light of a third color. The first color filter 182a, the second color filter 182b, and the third color filter 182c may be arranged to correspond to the emission area EA of the pixel PX. The first color filter 182a, the second color filter 182b, and the third color filter 182c may be arranged to be adjacent to each other. Each of the first color filter 182a, the second color filter 182b, and the third color filter 182c may have a separate pattern structure. Each of the first color filter 182a, the second color filter 182b, and the third color filter 182c may be arranged in an opening 183OP of the black matrix 183. Each of the first color filter 182a, the second color filter 182b, and the third color filter 182c may partially overlap the pixel-defining layer 119.

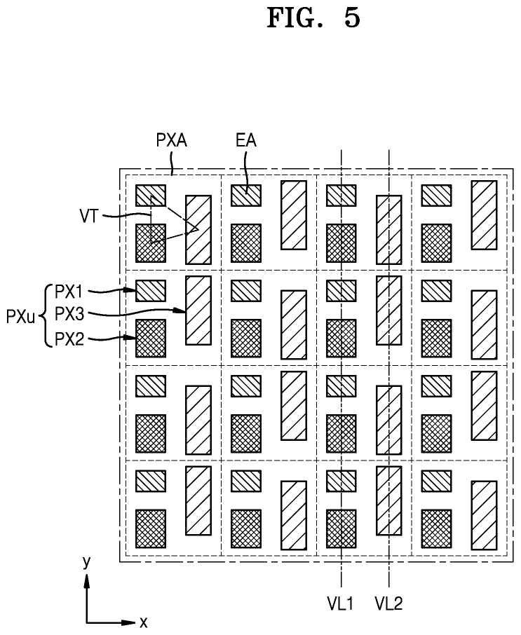

FIG. 5 illustrates arrangement of pixels according to an embodiment.

Unit pixel areas PXA may be defined in an x direction and a y direction in the display area DA of a display panel, and unit pixels PXu may be arranged in the unit pixel area PXA. The unit pixel PXu may include a first pixel PX1, a second pixel PX2, and a third pixel PX3. According to an embodiment, the first pixel PX1 may be a red pixel emitting red light, the second pixel PX2 may be a green pixel emitting green light, and the third pixel PX3 may be a blue pixel emitting blue light. The first pixel PX1, the second pixel PX2, and the third pixel PX3 may each include an organic light-emitting diode OLED, which is a display element, and a pixel circuit to which the organic light-emitting diode OLED is connected.

In the unit pixel area PXA, the display elements of the first pixel PX1, the second pixel PX2, and the third pixel PX3 may be arranged to have a predetermined pattern according to a predetermined rule. According to an embodiment, the unit pixel area PXA may have a rectangular shape.

A size and a shape of the emission area EA of the organic light-emitting diode OLED may be defined by an opening OP of the pixel-defining layer 119, and the emission area EA may be an area in which an emission layer of the organic light-emitting diode OLED is arranged. Thus, in this specification, the arrangement (alignment) of pixels may denote the arrangement (alignment) of display elements, the arrangement (alignment) of pixel electrodes, or the arrangement (alignment) of emission areas. FIG. 5 illustrates the emission areas EA corresponding to the organic light-emitting diode OLED of the first pixel PX1, the organic light-emitting diode OLED of the second pixel PX2, and the organic light-emitting diode OLED of the third pixel PX3, the first to third pixels PX1 to PX3 being arranged in the unit pixel area PXA.

According to an embodiment, as illustrated in FIG. 5, in the unit pixel area PXA, centers of the emission area EA of the first pixel PX1, the emission area EA of the second pixel PX2, and the emission area EA of the third pixel PX3 may be located at vertexes of a virtual triangle VT. In the unit pixel area PXA, the emission area EA of the first pixel PX1 and the emission area EA of the second pixel PX2 may be arranged to be adjacent to each other in the y direction, and the emission area EA of the third pixel PX3 may be arranged to be adjacent to the emission area EA of the first pixel PX1 and the emission area EA of the second pixel PX2 in the x direction. Accordingly, the emission area EA of the first pixel PX1 and the emission area EA of the second pixel PX2 may be alternately arranged with each other in the y direction along a first virtual straight line VL1, and the emission area EA of the third pixel PX3 may be repeatedly arranged in the y direction along a second virtual straight line VL2.

A length in the x direction and a length in the y direction of each of the emission area EA of the first pixel PX1, the emission area EA of the second pixel PX2, and the emission area EA of the third pixel PX3 may be different from each other. For example, the emission area EA of the first pixel PX1 may have a rectangular shape having a longer side extending in the x direction, and the emission area EA of the second pixel PX2 and the emission area EA of the third pixel PX3 may have a rectangular shape having a longer side extending in the y direction. A ratio between the length of the emission area EA of the first pixel PX1 in the x direction and the length of the emission area EA of the first pixel PX1 in the y direction, a ratio between the length of the emission area EA of the second pixel PX2 in the x direction and the length of the emission area EA of the second pixel PX2 in the y direction, and a ratio between the length of the emission area EA of the third pixel PX3 in the x direction and the length of the emission area EA of the third pixel PX3 in the y direction may be different from each other. According to another embodiment, the emission area EA of the first pixel PX1 and/or the emission area EA of the second pixel PX2 may have (a) rectangular shape(s) having the same lengths in the x direction and the y direction. The length of the emission area EA of the third pixel PX3 in the y direction may be equal to or greater than a sum of the length of the emission area EA of the first pixel PX1 in the y direction and the length of the emission area EA of the second pixel PX2 in the y direction. The rectangular-shaped emission area EA may also include a rectangular-shaped emission area having a round corner (vertex). According to an embodiment, the spacer SPC (FIG. 3) may be arranged between a pair of emission areas EA of the third pixel PX3 and another pair of emission areas EA of the third pixel PX3 in the y direction.

The emission area EA of the first pixel PX1, the emission area EA of the second pixel PX2, and the emission area EA of the third pixel PX3 may have different areas (sizes) from each other. According to an embodiment, the emission area EA of the third pixel PX3 may have a greater area than the emission area EA of the first pixel PX1. Also, the emission area EA of the third pixel PX3 may have a greater area than the emission area EA of the second pixel PX2. According to an embodiment, the emission area EA of the second pixel PX2 may have a greater area than the emission area EA of the first pixel PX1. According to another embodiment, the emission area EA of the first pixel PX1 may have the same area as the emission area EA of the second pixel PX2.

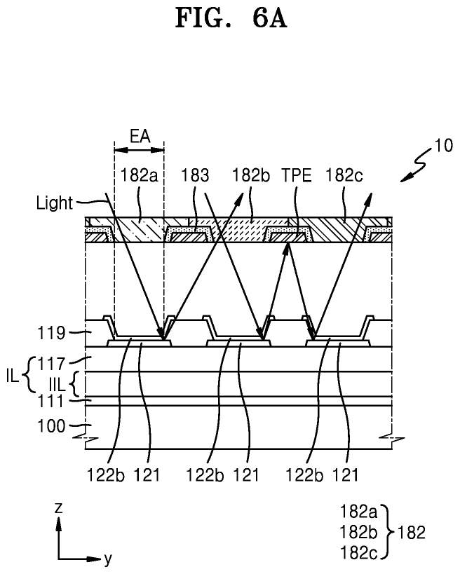

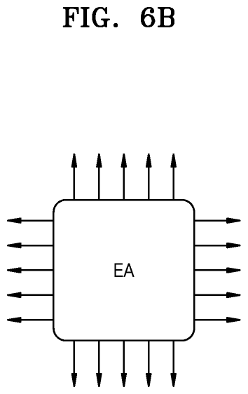

FIGS. 6A and 6B are example views for describing light reflection by an external light source. In FIG. 6A, some elements are omitted for convenience of illustration and explanation.

Referring to FIGS. 6A and 6B, as illustrated in FIG. 5, when a shape of the emission area is a polygon including straight-lined sides, a linear reflection-color-band and diffraction may occur along an edge of the emission area or the pixel-defining layer, due to diffused refection at the straight-lined edge of the pixel-defining layer, when a light source is incident to the display panel in a black state.

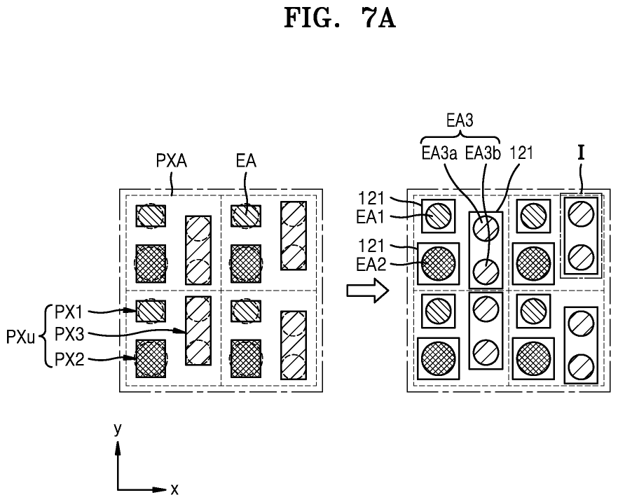

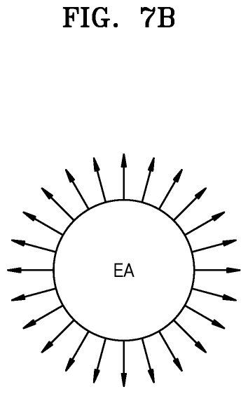

FIG. 7A illustrates an emission area according to an embodiment. FIG. 7B is an example view for describing light reflection by an external light source.

According to an embodiment, an organic light-emitting diode of the first pixel PX1, an organic light-emitting diode of the second pixel PX2, and an organic light-emitting diode of the third pixel PX3 may be arranged in the unit pixel area PXA, and each of a first emission area EA1 corresponding to the organic light-emitting diode of the first pixel PX1 and a second emission area EA2 corresponding to the organic light-emitting diode of the second pixel PX2 may be provided to have a closed curve shape. An emission area EA of the third pixel PX3 may include a 3-1^{st} sub-emission area EA3a and a 3-2^{nd} sub-emission area EA3b apart from each other, and each of the 3-1^{st} sub-emission area EA3a and the 3-2^{nd} sub-emission area EA3b may be provided to have a closed curve shape. For example, each of the first emission area EA1, the second emission area EA2, the 3-1^{st} sub-emission area EA3a, and the 3-2^{nd} sub-emission area EA3b may be provided to have a circular shape.

Referring to FIG. 7A, the first emission area EA1 of the first pixel PX1 and the second emission area EA2 of the second pixel PX2, the first and second emission areas EA1 and EA2 each being a rectangular emission area, may be changed to be circular emission areas. In FIG. 7A, a radius of the second emission area EA2 of the second pixel PX2 is illustrated to be greater than a radius of the first emission area EA1 of the first pixel PX1. However, the disclosure is not limited thereto. The radius of the second emission area EA2 may be the same as or less than the radius of the first emission area EA1. Like this, various modifications are possible.

A third emission area EA3 of the third pixel PX3, the third emission area EA3 having a rectangular shape having a long side in the y direction, may be changed to a pair of circular sub-emission areas EA3a and EA3b arranged to be adjacent to each other in the y direction. Accordingly, in the unit pixel area PXA, the first emission area EA1 of the first pixel PX1 and the 3-2^{nd} sub-emission area EA3b of the third pixel PX3 may be arranged to face each other in a diagonal direction, and the second emission area EA2 of the second pixel PX2 and the 3-1^{st} sub-emission area EA3a of the third pixel PX3 may be arranged to face each other in another diagonal direction. The pair of circular sub-emission areas EA3a and EA3b may have the same radius as each other. The radius of each of the pair of circular sub-emission areas EA3a and EA3b of the third pixel PX3 may be the same as the radius of the first emission area EA1 of the first pixel PX1.

Each of the first to third pixels PX1 to PX3 may include the organic light-emitting diode OLED, and the pixel electrode 121 of the organic light-emitting diode OLED may be arranged above the planarization layer 117. The pixel electrode 121 of each of the first to third pixels PX1 to PX3 may be provided to have a rectangular shape different from the shape of the emission area corresponding thereto. However, the disclosure is not limited thereto.

For example, the pixel electrode 121 of each of the first to third pixels PX1 to PX3 may be provided to have a similar shape as the emission area to which it corresponds. The pixel electrode 121 of the first pixel PX1 and the pixel electrode 121 of the second pixel PX2 may be provided to have a circular shape, and the pixel electrode 121 of the third pixel PX3 may be provided to have a dumbbell shape or a peanut shape in which circular shapes are arranged at both ends, and a bridge portion connects the two circular shapes.

According to another embodiment, the pixel electrode 121 of each of the first to third pixels PX1 to PX3 may be variously modified to have a rectangular shape with round edges, an oval shape, etc. The pixel electrode 121 may further include a contact hole (not shown) connected to members arranged below the pixel electrode 121. In this case, the pixel electrode 121 may have a portion having a shape corresponding to the contact hole.

In the case of a display panel using a color filter and a black matrix as an optical functional layer, different aperture ratios (opening ratios) may be required for pixels emitting different colors, due to the characteristics of the color filter. For example, as illustrated in FIG. 5, an aperture ratio of the third pixel PX3 may be greater than an aperture ratio of the first pixel PX1 and an aperture ratio of the second pixel PX2, in the display panel.

Like this, in the display panel having a pixel arrangement in which an aperture ratio of each pixel is different, a loss of aperture ratio may occur, when a rectangular emission area is changed to a circular emission area. The emission area may be provided to have various modified shapes, in order to minimize the loss of aperture ratio.

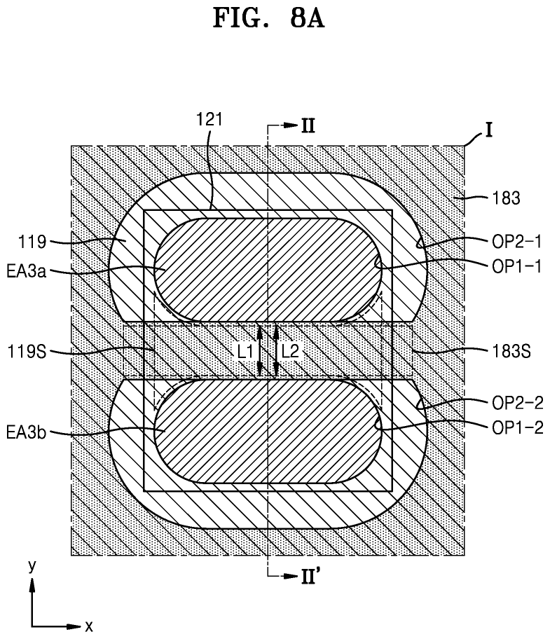

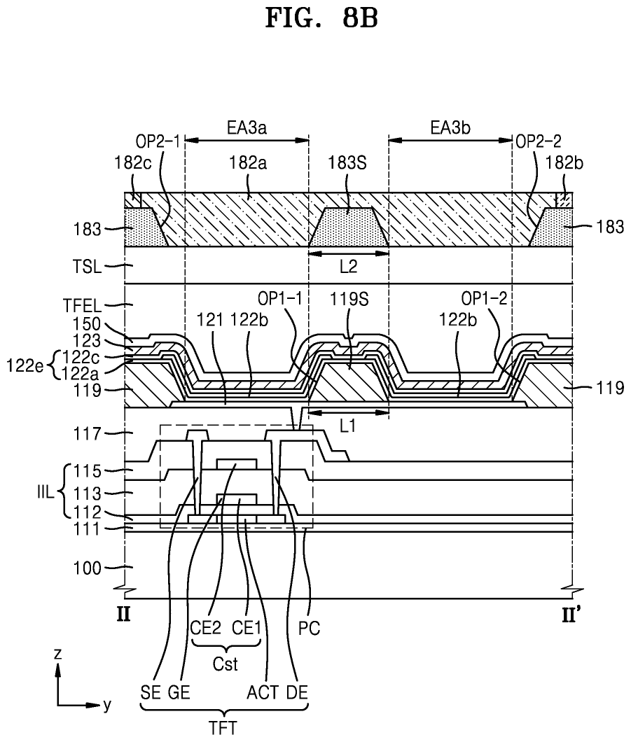

For example, the emission area may be provided to have an oval shape as illustrated in FIG. 8A.

FIG. 8A is a plan view showing arrangement of the third emission area EA3 of the third pixel PX3, the pixel defining layer 119, and the black matrix 183, according to an embodiment. FIG. 8B is a cross-sectional view of a region taken along a line II-II′ of FIG. 8A. For brevity of illustration, descriptions are to be given based on the third pixel PX3. However, the emission areas of the first pixel PX1 and the second pixel PX2 may also be provided to have various shapes based on arrangement of the black matrix 183 and the pixel-defining layer 119.

Referring to FIGS. 8A and 8B together, the display panel 10 may include the substrate 100, and the display layer DISL and the optical functional layer OFL on the substrate 100. The display layer DISL may include the pixel electrode 121 and the pixel-defining layer 119, and the optical functional layer OFL may include the black matrix 183 and the color filter 182.

According to the present embodiment, in the pixel electrode 121 of the third pixel PX3, the 3-1^{st} sub-emission area EA3a and the 3-2^{nd} sub-emission area EA3b may be arranged to be apart from each other. As illustrated in FIG. 8B, the pixel electrode 121 of the third pixel PX3 may contact the source electrode SE or the drain electrode DE through a via-hole of the planarization layer 117 to be electrically connected to the thin-film transistor TFT.

According to an embodiment, the pixel-defining layer 119 may have a first opening OP1 defining the third emission area EA3 on the pixel electrode 121. The pixel-defining layer 119 may include a display split portion 119S crossing the pixel electrode 121 in a plan view. By the display split portion 119S, the first opening OP1 defining the third emission area EA3 may be split into a 1-1^{st} opening OP1-1 and a 1-2^{nd} opening OP1-2. The 1-1^{st} opening OP1-1 may define the 3-1^{st} sub-emission area EA3a, and the 1-2^{nd} opening OP1-2 may define the 3-2^{nd} sub-emission area EA3b.

The emission layer 122b may be arranged in the 1-1^{st} opening OP1-1 and the 1-2^{nd} opening OP1-2. The emission layer 122b arranged in the 1-1^{st} opening OP1-1 and the 1-2^{nd} opening OP1-2 may emit the same color of light. The 1-1^{st} opening OP 1-1 and the 1-2^{nd} opening OP1-2 may be arranged on one pixel electrode 121.

The 1-1^{st} opening OP1-1 and the 1-2^{nd} opening OP1-2 may have various shapes. The 1-1^{st} opening OP1-1 and the 1-2^{nd} opening OP1-2 may have closed curve shapes. For example, the 1-1^{st} opening OP1-1 and the 1-2^{nd} opening OP1-2 may have circular or oval shapes. FIG. 8A illustrates that the 1-1^{st} opening OP1-1 and the 1-2^{nd} opening OP1-2 may have the same shape as each other. However, embodiments are not limited thereto. The 1-1^{st} opening OP1-1 and the 1-2^{nd} opening OP1-2 may have different shapes from each other. Also, the 1-1^{st} opening OP1-1 and the 1-2^{nd} opening OP1-2 may have the same shape as each other and different areas from each other.

According to the present embodiment, the black matrix 183 is formed in a first layer that covers the pixel electrode 121. The black matrix 183 may include a second opening OP2 positioned to correspond to the first opening OP1 of the pixel-defining layer 119, the pixel-defining layer being formed in a second layer that overlaps the first layer. The black matrix 183 may include an optical split portion 183S extending across the pixel electrode 121 that is under the first layer. The optical split portion 183S divides the second opening OP2 of the black matrix 183 into a 2-1^{st} opening OP2-1 and a 2-2^{nd} opening OP2-2.

The first color filter 182a may be arranged in the 2-1^{st} opening OP2-1 and the 2-2^{nd} opening OP2-2. That is, the color filter transmitting light of the same color may be arranged in the 2-1^{st} opening OP2-1 and the 2-2^{nd} opening OP2-2.

The 2-1^{st} opening OP2-1 and the 2-2^{nd} opening OP2-2 may have various shapes. FIG. 8B illustrates that each of the 2-1^{st} opening OP2-1 and the 2-2^{nd} opening OP2-2 may have a shape including a straight line and a curve. However, embodiments are not limited thereto. For example, the 2-1^{st} opening OP2-1 and the 2-2^{nd} opening OP2-2 may have closed curve shapes. The 2-1^{st} opening OP2-1 and the 2-2^{nd} opening OP2-2 may have circular or oval shapes. The 2-1^{st} opening OP2-1 and the 2-2^{nd} opening OP2-2 may have the same or substantially the same shape as the 1-1^{st} opening OP1-1 and the 1-2^{nd} opening OP1-2.

The 1-1^{st} opening OP1-1 and the 1-2^{nd} opening OP1-2 of the pixel-defining layer 119 may partially overlap the 2-1^{st} opening OP2-1 and the 2-2^{nd} opening OP2-2 of the black matrix 183, respectively.

The display split portion 119S and the optical split portion 183S may overlap each other. According to an embodiment, a first central width L1 of the display split portion 119S may be the same as a second central width L2 of the optical split portion 183S. The first central width L1 of the display split portion 119S may denote a distance between the 1-1^{st} opening OP1-1 and the 1-2^{nd} opening OP1-2 split by the display split portion 119S, and the second central width L2 of the optical split portion 183S may denote a distance between the 2-1^{st} opening OP2-1 and the 2-2^{nd} opening OP2-2 split by the optical split portion 183S. That the first central width L1 of the display split portion 119S may be the same as the second central width L2 of the optical split portion 183S may denote that lengths in the y direction from the same position in the x direction may be the same as each other.

In a general pixel structure, when the pixel-defining layer 119 and the black matrix 183 overlap each other in a z direction, there may be a limit that an open area of the black matrix has to be greater than an open area of the pixel-defining layer, in order to obtain a viewing angle of the display panel 10.

According to an embodiment, the optical split portion 183S of the black matrix 183 may extend across one pixel electrode 121 that is under the layer of the black matrix 183, and the 3-1^{st} sub-emission area EA3a and the 3-2^{nd} sub-emission area EA3b may emit light of the same color, and thus, with respect to an area between the 3-1^{st} sub-emission area EA3a and the 3-2^{nd} sub-emission area EA3b, the limit to obtain the viewing angle described above may not become an issue.

Accordingly, the second central width L2 of the optical split portion 183S may be substantially the same as the first central width L1 of the display split portion 119S. That is, while the 3-1^{st} sub-emission area EA3a and the 3-2^{nd} sub-emission area EA3b may be split by the display split portion 119S, the optical split portion 183S overlapping the display split portion 119S may have a wide area, in order to reduce reflection of external light.

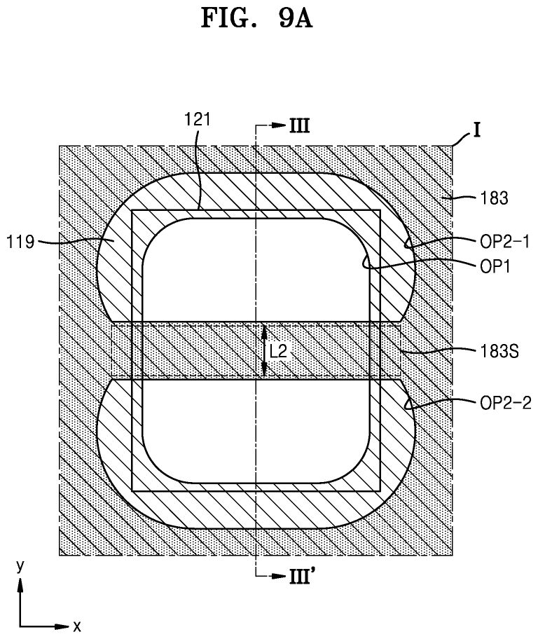

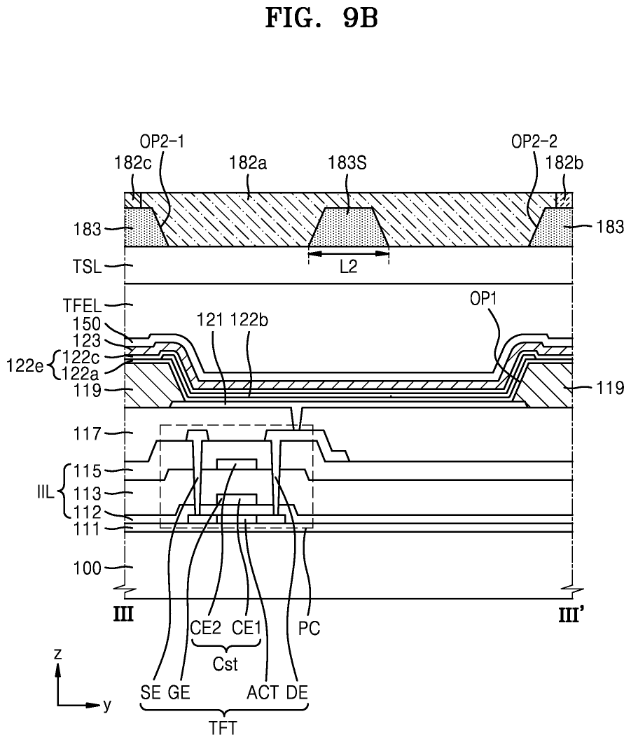

FIG. 9A is a plan view illustrating arrangement of an emission area of a pixel, a pixel-defining layer, and a black matrix, according to an embodiment. FIG. 9B is a cross-sectional view of a region taken along a line III-III′ of FIG. 9A. With respect to FIGS. 9A and 9B, the same reference numerals as FIGS. 8A and 8B may denote the same members, and thus, the same descriptions are not repeated.

Referring to FIG. 9A, according to an embodiment, the display split portion 119S of the pixel-defining layer 119 may be omitted. The first opening OP1 may be one opening that is not split. The third emission area EA3 may be defined by the first opening OP1 of the pixel-defining layer 119. The optical split portion 183S of the black matrix 183 may extend across the first opening OP1 hat is in a layer under the black matrix 183. The first opening OP1 may partially overlap the 2-1^{st} opening OP2-1 and the 2-2^{nd} opening OP2-2.

The first opening OP may have various shapes. Specifically, the first opening OP may have a closed curve shape. The first opening OP1 may have a circular or an oval shape. FIGS. 8A and 9A illustrate that each of the 2-1^{st} opening OP2-1 and the 2-2^{nd} opening OP2-2 has a shape including a straight line and a curve. However, embodiments are not limited thereto. Each of the 2-1^{st} opening OP2-1 and the 2-2^{nd} opening OP2-2 may have a closed curve shape. Each of the 2-1^{st} opening OP2-1 and the 2-2^{nd} opening OP2-2 may have a circular or an oval shape.

Referring to FIGS. 9A and 9B, the black matrix 183 that is in the first layer covering the pixel-defining layer 119 may include the optical split portion 183S. The optical split portion 183S extends across the first opening OP1 that is under the first layer. In the plan view, the first opening OP1 may be divided into multiple smaller openings by the optical split portion 183S. In the plan view, the third emission area EA3 may be split by the optical split portion 183S. The split third emission area EA3 may correspond to the 2-1^{st} opening OP2-1 and the 2-2^{nd} opening OP2-2 of the black matrix 183.

In other words, the third emission area EA3 of the third pixel PX3 may be divided by the optical split portion 183S in the plan view, even when the display split portion 119S described above is omitted. A shape of the split third emission area EA3 may be determined by a shape of the optical split portion 183S. By omitting the display split portion 119S arranged to overlap the optical split portion 183S, a degree of freedom with respect to the shape of the optical split portion 183S may be increased.

According to the display panel according to an embodiment, the black matrix 183, rather than the pixel-defining layer 119, may be arranged across one pixel electrode 121 in a plan view, and thus, an aperture ratio of a pixel may be increased, and an emission area may be divided into a predetermined shape through the black matrix 183.

The pixel-defining layer and the black matrix included in the display panel according to embodiments may have the arrangement relationship described above, and thus, reflection of external light may be prevented, and a reflection color band and diffraction phenomenon may be minimized.

The display apparatus including the organic light-emitting diode as the display element is described above for convenience of explanation. However, embodiments may be implemented in various types of display apparatuses, such as a liquid-crystal display apparatus, an electrophoretic display apparatus, an inorganic electroluminescent (EL) display apparatus, etc.

A display apparatus according to the embodiments may be realized as an electronic device, such as a smartphone, a cellular phone, a smart watch, a navigation device, a game machine, a television (TV), a vehicle head unit, a notebook computer, a laptop computer, a tablet computer, a personal media player (PMP), a personal digital assistant (PDA), etc. Also, the electronic device may be a flexible device.

According to the one or more of the embodiments described above, a display apparatus may include a black matrix including an optical split portion crossing a pixel electrode in a plan view, and thus, the display apparatus may minimize a loss of aperture ratio, prevent reflection of external light, and have improved display quality. However, the scope of the disclosure is not limited to these effects as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising a display layer and an optical functional layer on the display layer, wherein
the display layer includes a pixel electrode, a pixel-defining layer including a first opening defining an emission area on the pixel electrode, and an emission layer arranged in the first opening,
the optical functional layer includes a black matrix in a first layer that is covering the pixel electrode, the black matrix including a second opening above the first opening and a color filter in the second opening, and
the black matrix includes an optical split portion extending across the pixel electrode that is under the first layer.

2. The display panel of claim 1, wherein the second opening includes a 2-1^{st} opening and a 2-2^{nd} opening with the optical split portion therebetween.

3. The display panel of claim 2, wherein the color filter in the 2-1^{st} opening includes a same material as the color filter in the 2-2^{nd} opening.

4. The display panel of claim 2, wherein the first opening partially overlaps the 2-1^{st} opening and the 2-2^{nd} opening.

5. The display panel of claim 2, wherein the optical split portion extends across the first opening that is under the first layer.

6. The display panel of claim 1, wherein the pixel-defining layer is in a second layer that is covering the pixel electrode, the pixel-defining layer including a display split portion that extends across the pixel electrode that is under the second layer, wherein the display split portion divides the first opening into a 1-1^{st} opening and a 1-2^{nd} opening.

7. The display panel of claim 6, wherein the display split portion overlaps the optical split portion.

8. The display panel of claim 6, wherein a first central width of the display split portion is the same as a second central width of the optical split portion.

9. The display panel of claim 6, wherein the 1-1^{st} opening and the 1-2^{nd} opening have a closed shape.

10. The display panel of claim 9, wherein the 1-1^{st} opening and the 1-2^{nd} opening have a circular or an oval shape.

11. A display panel comprising a unit pixel area defined in a first direction and a second direction perpendicular to the first direction, wherein, in the unit pixel area, a first display element emitting light of a first color and a second display element emitting light of a second color are arranged to be adjacent to each other in the first direction, and a third display element emitting light of a third color is arranged to be adjacent to the first display element and the second display element in the second direction,
the third display element includes a third pixel electrode, a pixel-defining layer including a first opening defining a third emission area on the third pixel electrode, and a black matrix in a first layer that is covering the pixel electrode, the black matrix including a second opening above the first opening, and
the black matrix includes an optical split portion that extends across the third pixel electrode that is under the first layer.

12. The display panel of claim 11, wherein the second opening includes a 2-1^{st} opening and a 2-2^{nd} opening with the optical split portion therebetween.

13. The display panel of claim 12, further comprising a color filter selectively transmitting the light of the third color,
wherein the color filter is in the 2-1^{st} opening and the 2-2^{nd} opening.

14. The display panel of claim 12, wherein the first opening partially overlaps the 2-1^{st} opening and the 2-2^{nd} opening.

15. The display panel of claim 12, wherein the optical split portion extends across the first opening that is under the first layer.

16. The display panel of claim 11, wherein the pixel-defining layer includes a display split portion in a second layer that is covering the third pixel electrode, the display split portion extending across the third pixel electrode, and
the first opening includes a 1-1^{st} opening and a 1-2^{nd} opening with the display split portion therebetween.

17. The display panel of claim 16, wherein the display split portion overlaps the optical split portion.

18. The display panel of claim 16, wherein a central width of the display split portion is the same as a central width of the optical split portion.

19. The display panel of claim 16, wherein the 1-1^{st} opening and the 1-2^{nd} opening have a closed shape.

20. The display panel of claim 11, wherein the first color is red, the second color is green, and the third color is blue.
